(19) United States
(12) Patent Application Publication
(10) Pub. No.: US 2020/0203783 A1
(43) Pub. Date: Jun. 25, 2020

(54) BATTERY SWELLING DETECTION

(71) Applicant: Lenovo (Singapore) Pte. Ltd., Singapore (SG)

(72) Inventors: Justin Michael Ringuette, Morrisville, NC (US); Larry Glenn Estes, Durham, NC (US)

(21) Appl. No.: 16/229,334

(22) Filed: Dec. 21, 2018

(51) Int. Cl. H01M 10/48; H01M 2/34; G01R 31/382; H02J 7/00; G01R 31/36; G01R 31/392

(52) U.S. Cl. CPC H01M 10/488; H01M 2/34; G01R 31/382; H01M 2200/00; G01R 31/3644; G01R 31/392; H01M 2220/30; H02J 7/0029

(57) ABSTRACT

One embodiment provides a method, including: measuring, using a controller circuit of an information handling device, resistance of a printed resistive element coated onto a portion of a battery; identifying, based on the measuring, an aspect associated with battery swelling; determining, using a processor, whether the aspect is greater than a predetermined threshold; and triggering, responsive to determining that the aspect is greater than the predetermined threshold, execution of a remedial action. Other aspects are described and claimed.

### BACKGROUND

Batteries are common to and utilized in a variety of different information handling devices (“devices”), for example smart phones, tablet devices, laptop and personal computers, other electronic devices, and the like. Conventionally, the primary function of a battery may be to provide power to hardware components of a device when the device is disconnected from an alternative power source. In the case of rechargeable batteries (i.e., those batteries that can be charged, discharged into a load, and thereafter recharged, etc.), after an extended period of use these batteries may degrade and eventually fail.

### BRIEF SUMMARY

In summary, one aspect provides a method, comprising: measuring, using a controller circuit of an information handling device, resistance of a printed resistive element coated onto a portion of a battery; identifying, based on the measuring, an aspect associated with battery swelling; determining, using a processor, whether the aspect is greater than a predetermined threshold; and triggering, responsive to determining that the aspect is greater than the predetermined threshold, execution of a remedial action.

Another aspect provides an information handling device, comprising: a controller circuit; a battery; a processor; a memory device that stores instructions executable by the processor to: measure, using the controller circuit, resistance of a printed resistive element coated onto a portion of the battery; identify, based on the measuring, an aspect associated with battery swelling; determining, using a processor, whether the aspect is greater than a predetermined threshold; and trigger, responsive to determining that the aspect is greater than the predetermined threshold, execution of a remedial action.

A further aspect provides a product, comprising: a storage device that stores code, the code being executable by a processor and comprising: code that measures resistance of a printed resistive element coated onto a battery; code that identifies an aspect associated with battery swelling; code that determines whether the aspect is greater than a predetermined threshold; and code that triggers, responsive to determining that the aspect is greater than the predetermined threshold, execution of a remedial action.

The foregoing is a summary and thus may contain simplifications, generalizations, and omissions of detail; consequently, those skilled in the art will appreciate that the summary is illustrative only and is not intended to be in any way limiting.

For a better understanding of the embodiments, together with other and further features and advantages thereof, reference is made to the following description, taken in conjunction with the accompanying drawings. The scope of the invention will be pointed out in the appended claims.

### BRIEF DESCRIPTION OF THE SEVERAL VIEWS OF THE DRAWINGS

FIG. 1 illustrates an example of information handling device circuitry.

FIG. 2 illustrates another example of information handling device circuitry.

FIG. 3 illustrates an example method of detecting battery deformation.

### DETAILED DESCRIPTION

It will be readily understood that the components of the embodiments, as generally described and illustrated in the figures herein, may be arranged and designed in a wide variety of different configurations in addition to the described example embodiments. Thus, the following more detailed description of the example embodiments, as represented in the figures, is not intended to limit the scope of the embodiments, as claimed, but is merely representative of example embodiments.

Reference throughout this specification to “one embodiment” or “an embodiment” (or the like) means that a particular feature, structure, or characteristic described in connection with the embodiment is included in at least one embodiment. Thus, the appearance of the phrases “in one embodiment” or “in an embodiment” or the like in various places throughout this specification are not necessarily all referring to the same embodiment.

Furthermore, the described features, structures, or characteristics may be combined in any suitable manner in one or more embodiments. In the following description, numerous specific details are provided to give a thorough understanding of embodiments. One skilled in the relevant art will recognize, however, that the various embodiments can be practiced without one or more of the specific details, or with other methods, components, materials, et cetera. In other instances, well known structures, materials, or operations are not shown or described in detail to avoid obfuscation.

Swelling, or bloating, is a common occurrence in rechargeable batteries (e.g., lithium-ion batteries, etc.). In such instances, portions of the battery may actually enlarge so as to manipulate, or warp, the battery's standard shape. Generally, swelling is a result of gases that are produced due to electrochemical oxidation of the electrolyte. Such oxidation is usually a result of: overcharging the battery, extensive use of the battery, a faulty battery, faulty charging electronics in a device or battery charger, a combination thereof, and the like. A swollen battery may not be able to properly interface with surrounding circuitry in an electronic device due to its warped shaped, which may lead to mechanical failure. Additionally, a swollen battery may be a fire hazard due to the potential buildup of gases within the battery coupled with the battery's integration in a larger electronic device. The detection of a swelling condition prior to mechanical failures allows for interventions such as alerting a user, changing charge parameters, disabling charging, etc.

A conventional method of battery swelling detection involves the electrical measurement of battery cells to infer capacity and cell health. A swollen battery cell that has reduced capacity will be detected by this method. However, not all swelling events cause significant changes in electrical characteristics prior to failure. Additionally, capacity degradation cannot be measured instantaneously, but rather, commonly requires hours or even days of measurement to detect depending on usage conditions. Another conventional method of battery swelling detection involves the use of discrete pressure sensors, such as piezoelectric pads, which can be used to directly measure pressure between the cell and the exterior surface. However, these sensors are generally too large and expensive for use by the common consumer in notebooks, smartphones, and other small, cost-sensitive devices.

Accordingly, an embodiment provides a method for effectively detecting battery swelling by utilizing conductive ink, or a similar printed resistive element, that is spread across the cell body and measured (e.g., as a resistor or fuse) by a controller circuit. In an embodiment, resistance of a printed resistive element (e.g., such as conductive ink, etc.) coated onto a battery may be measured using a controller circuit. An embodiment may then identify, based on these measurements, an aspect of battery swelling. For example, in an embodiment, an aspect may correspond to the measurement of a battery swelling level (i.e., an objective value associated with the magnitude of battery swelling/deformation), a battery swelling rate (i.e., an objective rate value associated with the rate at which a battery is swelling/deforming), a combination thereof, and the like. An embodiment may then determine whether the aspect is greater than a predetermined threshold (e.g., a critical swelling level, a critical swelling rate, etc.). Responsive to determining that the aspect is greater than the predetermined threshold, an embodiment may trigger execution of a remedial action (e.g., provision of a notification to a user, disconnection of the battery from the system, decrease in maximum battery charge, etc.). Such a method may limit or prevent occurrences of mechanical malfunction of a device due to battery swelling. Additionally, such a method may be utilized in a variety of different type of electronics, both large and small, and is much cheaper to implement than conventional battery swelling measurement systems.

The illustrated example embodiments will be best understood by reference to the figures. The following description is intended only by way of example, and simply illustrates certain example embodiments.

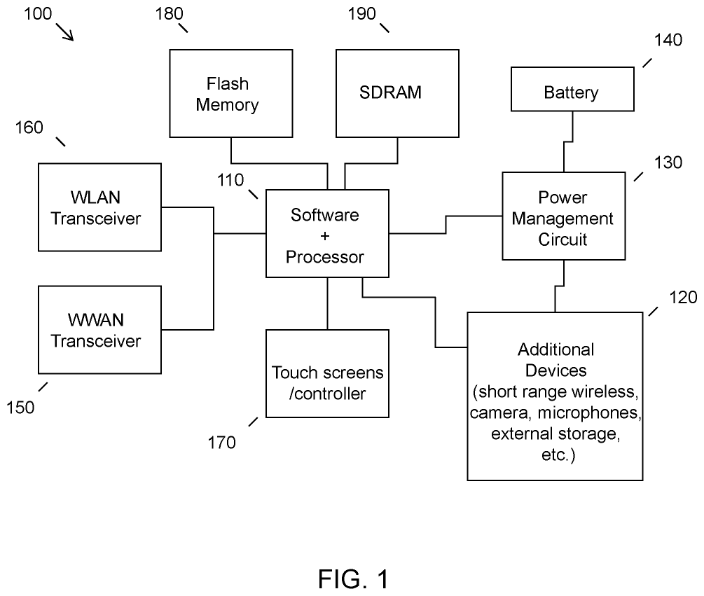

While various other circuits, circuitry or components may be utilized in information handling devices, with regard to smart phone and/or tablet circuitry 100, an example illustrated in FIG. 1 includes a system on a chip design found for example in tablet or other mobile computing platforms. Software and processor(s) are combined in a single chip 110. Processors comprise internal arithmetic units, registers, cache memory, busses, I/O ports, etc., as is well known in the art. Internal busses and the like depend on different vendors, but essentially all the peripheral devices (120) may attach to a single chip 110. The circuitry 100 combines the processor, memory control, and I/O controller hub all into a single chip 110. Also, systems 100 of this type do not typically use SATA or PCI or LPC. Common interfaces, for example, include SDIO and I2C.

There are power management chip(s) 130, e.g., a battery management unit, BMU, which manage power as supplied, for example, via a rechargeable battery 140, which may be recharged by a connection to a power source (not shown). In at least one design, a single chip, such as 110, is used to supply BIOS like functionality and DRAM memory.

System 100 typically includes one or more of a WWAN transceiver 150 and a WLAN transceiver 160 for connecting to various networks, such as telecommunications networks and wireless Internet devices, e.g., access points. Additionally, devices 120 are commonly included, e.g., an image sensor such as a camera, audio capture device such as a microphone, motion sensor such as an accelerometer or gyroscope, a thermal sensor, etc. System 100 often includes one or more touch screens 170 for data input and display/rendering. System 100 also typically includes various memory devices, for example flash memory 180 and SDRAM 190.

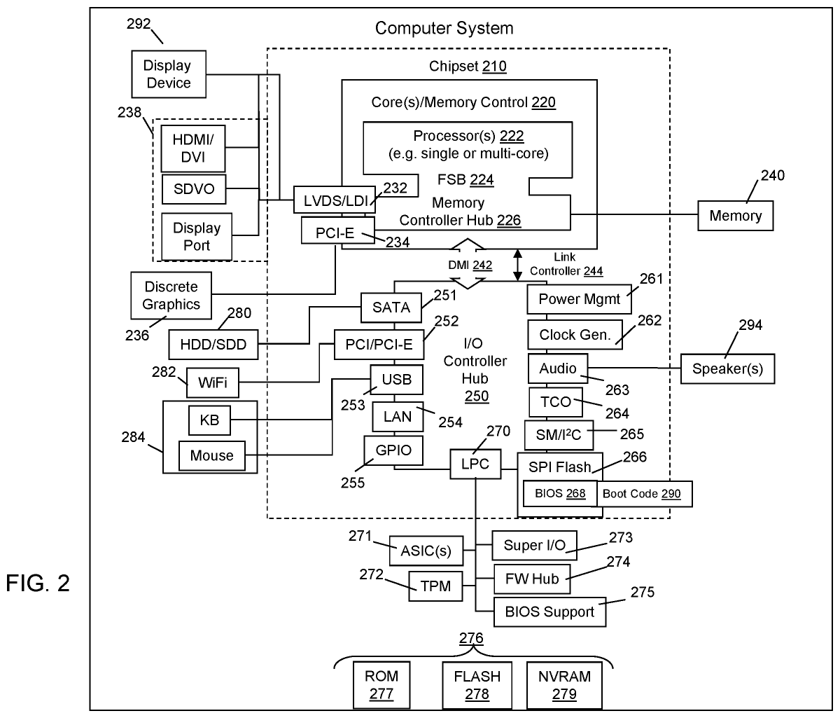

FIG. 2 depicts a block diagram of another example of information handling device circuits, circuitry or components. The example depicted in FIG. 2 may correspond to computing systems such as the THINKPAD series of personal computers sold by Lenovo (US) Inc. of Morrisville, N.C., or other devices. As is apparent from the description herein, embodiments may include other features or only some of the features of the example illustrated in FIG. 2.

The example of FIG. 2 includes a so-called chipset 210 (a group of integrated circuits, or chips, that work together, chipsets) with an architecture that may vary depending on manufacturer (for example, INTEL, AMD, ARM, etc.). INTEL is a registered trademark of Intel Corporation in the United States and other countries. AMD is a registered trademark of Advanced Micro Devices, Inc. in the United States and other countries. ARM is an unregistered trademark of ARM Holdings plc in the United States and other countries. The architecture of the chipset 210 includes a core and memory control group 220 and an I/O controller hub 250 that exchanges information (for example, data, signals, commands, etc.) via a direct management interface (DMI) 242 or a link controller 244. In FIG. 2, the DMI 242 is a chip-to-chip interface (sometimes referred to as being a link between a “northbridge” and a “southbridge”). The core and memory control group 220 include one or more processors 222 (for example, single or multi-core) and a memory controller hub 226 that exchange information via a front side bus (FSB) 224; noting that components of the group 220 may be integrated in a chip that supplants the conventional “northbridge” style architecture. One or more processors 222 comprise internal arithmetic units, registers, cache memory, busses, I/O ports, etc., as is well known in the art.

In FIG. 2, the memory controller hub 226 interfaces with memory 240 (for example, to provide support for a type of RAM that may be referred to as “system memory” or “memory”). The memory controller hub 226 further includes a low voltage differential signaling (LVDS) interface 232 for a display device 292 (for example, a CRT, a flat panel, touch screen, etc.). A block 238 includes some technologies that may be supported via the LVDS interface 232 (for example, serial digital video, HDMI/DVI, display port). The memory controller hub 226 also includes a PCI-express interface (PCI-E) 234 that may support discrete graphics 236.

In FIG. 2, the I/O hub controller 250 includes a SATA interface 251 (for example, for HDDs, SDDs, etc., 280), a PCI-E interface 252 (for example, for wireless connections 282), a USB interface 253 (for example, for devices 284 such as a digitizer, keyboard, mice, cameras, phones, microphones, storage, other connected devices, etc.), a network interface 254 (for example, LAN), a GPIO interface 255, a LPC interface 270 (for ASICs 271, a TPM 272, a super I/O 273, a firmware hub 274, BIOS support 275 as well as various types of memory 276 such as ROM 277, Flash 278, and NVRAM 279), a power management interface 261, a clock generator interface 262, an audio interface 263 (for example, for speakers 294), a TCO interface 264, a system management bus interface 265, and SPI Flash 266, which can include BIOS 268 and boot code 290. The I/O hub controller 250 may include gigabit Ethernet support.

The system, upon power on, may be configured to execute boot code 290 for the BIOS 268, as stored within the SPI Flash 266, and thereafter processes data under the control of one or more operating systems and application software (for example, stored in system memory 240). An operating system may be stored in any of a variety of locations and accessed, for example, according to instructions of the BIOS 268. As described herein, a device may include fewer or more features than shown in the system of FIG. 2.

Information handling device circuitry, as for example outlined in FIG. 1 or FIG. 2, may be used in devices such as smart phones, tablets, laptop and notebook computers, personal computer devices generally, and/or electronic devices that utilize batteries to obtain electrical energy. For example, the circuitry outlined in FIG. 1 may be implemented in a tablet or smart phone embodiment, whereas the circuitry outlined in FIG. 2 may be implemented in a laptop embodiment.

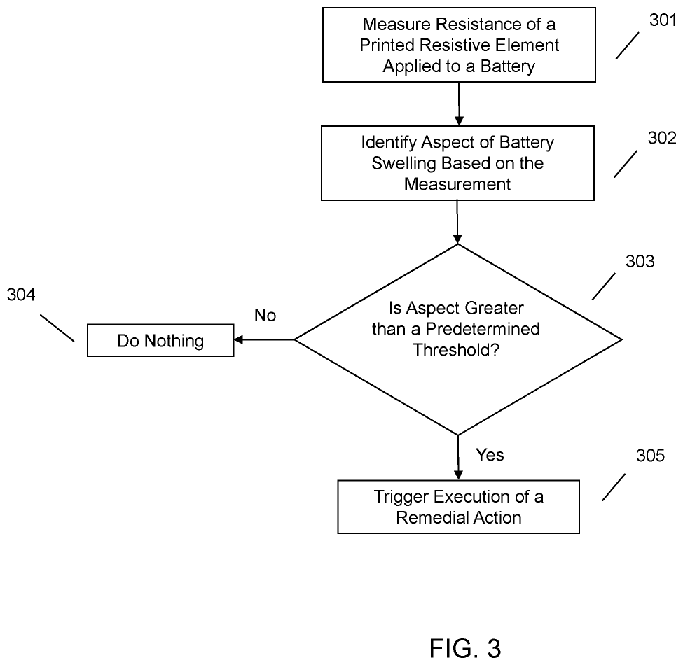

Referring now to FIG. 3, an embodiment may trigger a remedial action responsive to determining that a battery has swelled past a critical point or is swelling at a critical rate. At 301, an embodiment may measure resistance of a printed resistive element coated onto a portion of a battery. In an embodiment, the printed resistive element may be an element such as conductive ink (i.e., ink infused with graphite or other conductive materials that result in a printed object which conducts electricity). For simplicity purposes, the remaining disclosure will be discussed using conductive ink as the printed resistive element. However, this designation is not intended to be limiting, and one skilled in the art would recognize that other printed resistive elements may also be utilized.

In an embodiment, the conductive ink may be coated onto a portion of the battery. For instance, a line of conductive ink may be drawn around the outer circumference, or outer surface, of the battery at one or more portions. Alternatively, in another embodiment, the conductive ink may be coated around the entirety of the battery sides, effectively covering the battery in conductive ink.

In an embodiment, the conductive ink will change resistance in response to battery cell swelling as the material deforms; increasing in resistance if the battery cell surface spreads apart or decreasing in resistance if the battery cell surface presses together. This change in resistance may then be measured (e.g., continuously, at predetermined time intervals, etc.) by a controller circuit to detect if swelling has actually occurred (e.g., by reference to an accessible data reference table, etc.). This detection may be digital (i.e., the detection of whether swelling has occurred or not) or analog (i.e., the detection of an amount of swelling) depending on circuit design and ink topography. For instance, one embodiment may utilize ink as part of a 2-resistor voltage divider circuit feeding an analog-to-digital converter (“ADC”), in which the ADC's detected voltage would increase and decrease in proportion to swelling. Accordingly, such a measurement method may produce a numerical result (e.g., between 0-1024 ohms) that is associated with a degree of swelling that has occurred. Other embodiments include use as a fusible element or as input to an operational amplifier (“op-amp”) to trigger a signal change at a specific swelling threshold.

At 302, an embodiment may identify, based on the foregoing measurements, an aspect associated with battery swelling. In an embodiment, the aspect may correspond to a battery swelling level. The battery swelling level may be an amount by which a battery has swollen from its original shape. Additionally or alternatively, the battery swelling level may be an amount by which the conductive ink has increased in resistance. This amount may be equated to the amount by which a battery has swollen by utilizing a reference table comprising corresponding values between ink resistance and battery swell size for the particular battery that the conductive ink is coated on.

In an embodiment, the aspect may correspond to a battery swelling rate. The battery swelling rate may be a rate by which the battery is swelling. Additionally or alternatively, the battery swelling rate may be a rate by which the resistance of the conductive ink is increasing. This rate may be equated to the rate by which a battery is swelling by utilizing a reference table comprising corresponding values between ink expansion rate and battery swell rate for the particular battery that the conductive ink is coated on

At 303, an embodiment may determine whether the aspect is greater than a predetermined threshold. In an embodiment, the predetermined threshold may correspond to a critical swelling limit. More particularly, in an embodiment, the critical swelling limit may be a limit, over which, issues are likely to occur if the battery continues to swell. The critical swelling limit may be represented by an objective, numerical value that may be designated by a manufacturer, adjusted by a user, or obtained via another source (e.g., a crowdsourced number obtained from the Internet, etc.). In another embodiment, the predetermined threshold may correspond to a critical swelling rate. More particularly, in an embodiment, the critical swelling rate may be a rate, over which, issues are likely to occur if the battery swells any faster.

Responsive to determining, at 303, that the aspect is not greater than the predetermined threshold, an embodiment may, at 304, not execute any remedial action. Responsive to determining, at 303, that the aspect is greater than the predetermined threshold, an embodiment may, at 305, trigger execution of a remedial action. The remedial action may be one or more of the subsequently described actions. For instance, in an embodiment, the remedial action may provision of a notification to a user. The notification may apprise the user that a battery swelling level, a battery swelling rate, a combination thereof, etc. are greater than a predetermined threshold. The notification may be provided to the user using one or more conventional methods (e.g., visual notification, audible notification, haptic notification, a combination thereof, and the like). In another embodiment, the remedial action may be a disconnecting of the battery from the surrounding system of the device it is providing power to. Such an action may limit the damage to any surrounding circuitry, limit the deformation incurred by the battery, and decrease the chance of a fire. In yet another embodiment, the remedial action may be a decrease in the maximum charge level of the battery. For instance, if the battery has begun to swell due to being at a high state of charge for an extended period of time, the battery firmware may be able to detect that and decrease the maximum charge level of the battery. So for example, instead of charging fully to 100%, it charges up to 80% and stops. In an embodiment, the triggering of the remedial action may occur automatically and without any additional user input.

In some cell constructions in batteries a natural amount of swelling may occur in charge and discharge cycles. In these cycles, the battery “breathes” as it is charging, figuratively exhaling and inhaling, as gas is generated and then reabsorbed. An embodiment may be able to detect aspects associated with the natural swelling (e.g., known natural swell values and rates, etc.) and thereafter determine whether an identified battery swelling level or a battery swelling rate may simply be associated with natural swelling. Responsive to determining that an identified value is associated with a natural swelling value, an embodiment may, at 304, take no remedial action.

The various embodiments described herein thus represent a technical improvement to conventional battery swelling detection techniques. Using the techniques described herein, an embodiment may measure the resistance of a printed resistive element coated onto a portion of a battery of a device. An embodiment may thereafter identify an aspect associated with battery swelling based upon the aspect and thereafter determine if the aspect is greater than a predetermined threshold. Responsive to determining that the aspect is greater than the predetermined threshold, an embodiment may trigger a remedial action to be executed. Such techniques allow for the cost-effective and real time detection of battery swelling.

As will be appreciated by one skilled in the art, various aspects may be embodied as a system, method or device program product. Accordingly, aspects may take the form of an entirely hardware embodiment or an embodiment including software that may all generally be referred to herein as a “circuit,” “module” or “system.” Furthermore, aspects may take the form of a device program product embodied in one or more device readable medium(s) having device readable program code embodied therewith.

It should be noted that the various functions described herein may be implemented using instructions stored on a device readable storage medium such as a non-signal storage device that are executed by a processor. A storage device may be, for example, a system, apparatus, or device (e.g., an electronic, magnetic, optical, electromagnetic, infrared, or semiconductor system, apparatus, or device) or any suitable combination of the foregoing. More specific examples of a storage device/medium include the following: a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a storage device is not a signal and “non-transitory” includes all media except signal media.

Program code embodied on a storage medium may be transmitted using any appropriate medium, including but not limited to wireless, wireline, optical fiber cable, RF, et cetera, or any suitable combination of the foregoing.

Program code for carrying out operations may be written in any combination of one or more programming languages. The program code may execute entirely on a single device, partly on a single device, as a stand-alone software package, partly on single device and partly on another device, or entirely on the other device. In some cases, the devices may be connected through any type of connection or network, including a local area network (LAN) or a wide area network (WAN), or the connection may be made through other devices (for example, through the Internet using an Internet Service Provider), through wireless connections, e.g., near-field communication, or through a hard wire connection, such as over a USB connection.

Example embodiments are described herein with reference to the figures, which illustrate example methods, devices and program products according to various example embodiments. It will be understood that the actions and functionality may be implemented at least in part by program instructions. These program instructions may be provided to a processor of a device, a special purpose information handling device, or other programmable data processing device to produce a machine, such that the instructions, which execute via a processor of the device implement the functions/acts specified.

It is worth noting that while specific blocks are used in the figures, and a particular ordering of blocks has been illustrated, these are non-limiting examples. In certain contexts, two or more blocks may be combined, a block may be split into two or more blocks, or certain blocks may be re-ordered or re-organized as appropriate, as the explicit illustrated examples are used only for descriptive purposes and are not to be construed as limiting.

As used herein, the singular “a” and “an” may be construed as including the plural “one or more” unless clearly indicated otherwise.

This disclosure has been presented for purposes of illustration and description but is not intended to be exhaustive or limiting. Many modifications and variations will be apparent to those of ordinary skill in the art. The example embodiments were chosen and described in order to explain principles and practical application, and to enable others of ordinary skill in the art to understand the disclosure for various embodiments with various modifications as are suited to the particular use contemplated.

Thus, although illustrative example embodiments have been described herein with reference to the accompanying figures, it is to be understood that this description is not limiting and that various other changes and modifications may be affected therein by one skilled in the art without departing from the scope or spirit of the disclosure.

What is claimed is:

1. A method, comprising:
measuring, using a controller circuit of an information handling device, resistance of a printed resistive element coated onto a portion of a battery;
identifying, based on the measuring, an aspect associated with battery swelling;
determining, using a processor, whether the aspect is greater than a predetermined threshold; and
triggering, responsive to determining that the aspect is greater than the predetermined threshold, execution of a remedial action.

2. The method of claim 1, wherein the printed resistive element is conductive ink.

3. The method of claim 1, wherein the measuring comprises measuring the resistance of the printed resistive element at predetermined intervals.

4. The method of claim 1, wherein the aspect corresponds to a battery swelling level and wherein the predetermined threshold corresponds to a critical point.

5. The method of claim 1, wherein the aspect corresponds to a battery swelling rate and wherein the predetermined threshold corresponds to a critical rate.

6. The method of claim 1, wherein the triggering comprises automatically triggering without additional user input.

7. The method of claim 1, wherein the triggering the remedial action comprises providing, to a user, a notification that a battery swelling level or a battery swelling rate is greater than the predetermined threshold.

8. The method of claim 1, wherein the triggering the remedial action comprises disconnecting the battery from a system of the information handling device.

9. The method of claim 1, wherein the triggering the remedial action comprises decreasing a maximum charge level of the battery.

10. The method of claim 1, further comprising:
identifying, using a processor, a natural swelling cycle;
determining, using a processor, whether the aspect corresponds to the natural swelling cycle; and
not triggering, responsive to determining that the aspect corresponds to the natural swelling cycle; execution of the remedial action
wherein the aspect corresponds to a battery swelling rate.

11. An information handling device, comprising:
a controller circuit;
a battery;
a processor;
a memory device that stores instructions executable by the processor to:
measure, using the controller circuit, resistance of a printed resistive element coated onto a portion of the battery;
identify, based on the measuring, an aspect associated with battery swelling;
determining, using a processor, whether the aspect is greater than a predetermined threshold; and
trigger, responsive to determining that the aspect is greater than the predetermined threshold, execution of a remedial action.

12. The information handling device of claim 11, wherein the printed resistive element is conductive ink.

13. The information handling device of claim 11, wherein the aspect corresponds to a battery swelling level and wherein the predetermined threshold corresponds to a critical point.

14. The information handling device of claim 11, wherein the aspect corresponds to a battery swelling rate and wherein the predetermined threshold corresponds to a critical rate.

15. The information handling device of claim 11, wherein the instructions executable by the processor to trigger comprise instructions executable by the processor to automatically trigger without additional user input.

16. The information handling device of claim 11, wherein the instructions executable by the processor to trigger the remedial action comprise instructions executable by the processor to provide, to a user, a notification that a battery swelling level or a battery swell rate is greater than a predetermined threshold.

17. The information handling device of claim 11, wherein the instructions executable by the processor to trigger the remedial action comprise instructions executable by the processor to disconnect the battery from a system associated with the information handling device.

18. The information handling device of claim 11, wherein the instructions executable by the processor to trigger the remedial action comprise instructions executable by the processor to decrease a maximum charge level of the battery.

19. The information handling device of claim 11, wherein the instructions are further executable by the processor to:
identify a natural swelling cycle;
determine whether the aspect corresponds to the natural swelling cycle; and
not trigger, responsive to determining that the aspect corresponds to the natural swelling cycle; execution of the remedial action
wherein the aspect corresponds to a battery swelling rate.

20. A product, comprising:
a storage device that stores code, the code being executable by a processor and comprising:
code that measures resistance of a printed resistive element coated onto a battery;
code that identifies an aspect associated with battery swelling;
code that determines whether the aspect is greater than a predetermined threshold; and
code that triggers, responsive to determining that the aspect is greater than the predetermined threshold, execution of a remedial action.
